(19) United States
(12) Patent Application Publication
(10) Pub. No.: US 2025/0132185 A1
(43) Pub. Date: Apr. 24, 2025

(54) COOLING SYSTEM FOR SEMICONDUCTOR EQUIPMENT

(71) Applicant: Samsung Electronics Co., Ltd., Suwon-si (KR)

(72) Inventors: Jonghwa Kim, Suwon-si (KR); Daeho Min, Suwon-si (KR); Yunha Kim, Suwon-si (KR); Kwanghyun Cho, Suwon-si (KR); Kyeongbin Lim, Suwon-si (KR)

(21) Appl. No.: 18/825,121

(22) Filed: Sep. 5, 2024

(30) Foreign Application Priority Data
Oct. 20, 2023 (KR) 10-2023-0140969

(51) Int. Cl. H01L 21/683; H01L 21/67

(52) U.S. Cl. CPC H01L 21/6833; H01L 21/67109

(57) ABSTRACT

A cooling system for semiconductor equipment includes a chamber, an electrostatic chuck in the chamber, a coolant pipe housing in at least one of the chamber and the electrostatic chuck, the coolant pipe housing having an internal space, a coolant pipe at least partially in the internal space of the coolant pipe housing, and a flow controller configured to control a flow velocity of the coolant flowing along the coolant pipe so that the flow velocity periodically reaches a highest speed and a lowest speed.

### CROSS-REFERENCE TO RELATED APPLICATION(S)

This application claims benefit of priority to Korean Patent Application No. 10-2023-0140969, filed Oct. 20, 2023, in the Korean Intellectual Property Office, the disclosure of which is incorporated herein by reference in its entirety.

### BACKGROUND

The present inventive concept relates to a cooling system for semiconductor equipment.

If a temperature changes significantly, it may affect products produced by a process due to changes in physical/chemical properties depending on a process temperature. A coolant is used to change the temperature quickly and accurately to a target temperature or maintain the target temperature.

Here, the temperature of the coolant gradually changes temporally and spatially along a coolant flow path due to heat exchange with a target object.

The efficiency (cooling ability) of the coolant is proportional to the size of a temperature difference between the coolant and the target object, so the temperature of the target object becomes spatially inconsistent due to the change in coolant temperature, which ultimately degrades the uniformity of the process results.

### SUMMARY

An aspect of the present inventive concept is to provide a cooling system for semiconductor equipment, capable of improving temperature uniformity of a wafer.

According to the present inventive concept, a cooling system for semiconductor equipment includes a chamber, an electrostatic chuck in the chamber, a coolant pipe housing in at least one of the chamber and the electrostatic chuck, the coolant pipe housing having an internal space, a coolant pipe at least partially in the internal space of the coolant pipe housing, and a flow controller configured to control a flow velocity of a coolant flowing along the coolant pipe so that the flow velocity periodically reaches a highest speed and a lowest speed.

According to the present inventive concept, a cooling system for semiconductor equipment includes a chamber; and an electrostatic chuck in the chamber, wherein the electrostatic chuck includes a top plate on which a wafer is seated, a coolant pipe housing below the top plate; a coolant pipe housing below the top plate and having an internal space; and a coolant pipe at least partially in in the internal space of the coolant pipe housing. The cooling system further includes a flow controller configured to control a flow velocity of a coolant flowing through the coolant pipe so that the flow velocity changes periodically over time.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view of semiconductor equipment according to an example embodiment;

FIG. 2 is a cross-sectional view illustrating an electrostatic chuck according to an example embodiment;

FIG. 3 is a perspective view illustrating a coolant pipe provided in an electrostatic chuck according to an example embodiment;

FIGS. 4 to 10 are graphs illustrating a flow velocity of a coolant flowing along a coolant pipe over time according to an example embodiment;

FIG. 11 is a graph illustrating a flow velocity of a coolant flowing in an electrostatic chuck over time according to the related art and example embodiments;

FIG. 12 is a graph illustrating a temperature distribution of a wafer by an electrostatic chuck according to the related art;

FIG. 13 is a view illustrating a temperature distribution of a wafer by an electrostatic chuck according to an example embodiment;

FIG. 14 is a graph illustrating a flow velocity of a coolant flowing in an electrostatic chuck according to the related art and example embodiments over time;

FIG. 15 is a view illustrating a temperature distribution of a wafer by an electrostatic chuck according to an example embodiment;

FIG. 16 is a graph illustrating temperature stabilization time by an electrostatic chuck according to the related art and example embodiments; and

FIG. 17 is a graph illustrating process temperature stabilization time by an electrostatic chuck according to the related art and example embodiments.

### DETAILED DESCRIPTION

Hereinafter, example embodiments of the present inventive concept will be described with reference to the accompanying drawings.

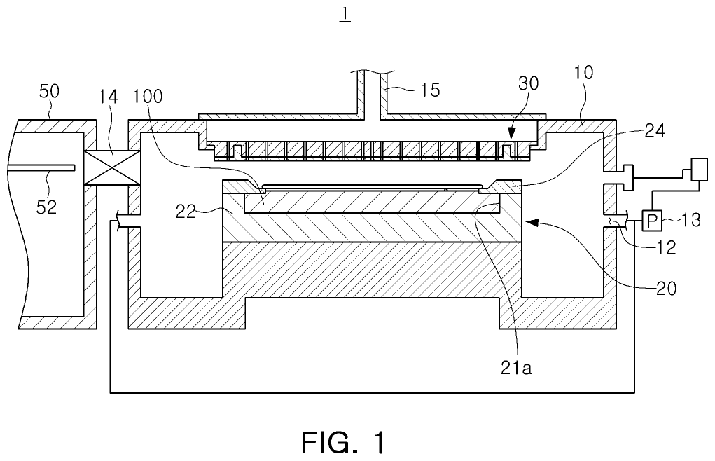

FIG. 1 is a cross-sectional view of semiconductor equipment according to an example embodiment.

Referring to FIG. 1, semiconductor equipment 1 may be an etching device, for example. However, the present inventive concept is not limited thereto, and the semiconductor equipment 1 may be semiconductor manufacturing equipment, such as an etching device or a deposition device, or may be semiconductor inspection equipment. The semiconductor equipment 1 includes a chamber 10 into which a wafer (not illustrated) is loaded. The chamber 10 provides a space for performing an etching process on the loaded wafer, and includes a susceptor 20 including an electrostatic chuck 100 on which the wafer is seated and an upper electrode 30 above the susceptor 20. Each of the susceptor 20 and the upper electrode 30 may have a substantially cylindrical shape.

The chamber 10 is connected to a pressure reducing device 13 (e.g., a vacuum pump) through an exhaust pipe 12 in a certain region. Accordingly, the chamber 10 may provide a low internal pressure required for excellent etching characteristics. In addition, a gate valve 14 is on a sidewall of the chamber 10, and a load lock chamber 50 having a wafer transfer arm 52 is connected to the gate valve 14.

Referring to an operation of loading a wafer into the chamber 10, the pressure of the load lock chamber 50 is reduced to a level similar to the pressure of the chamber 10, and then the wafer is loaded from the load lock chamber 50 to the chamber 10 using the wafer transfer arm 52. Thereafter, the wafer transfer arm 52 is removed from the chamber 10 to the load lock chamber 50, and then the gate valve 14 is closed. In addition, as an example, an upper portion of the chamber 10 may be connected to a gas inlet 15 for supplying gases for an etching process.

The electrostatic chuck 100 is on the top of the susceptor 20 to fix the wafer. A detailed description of the electrostatic chuck 100 will be provided below.

A fixed chuck 21 includes an installation recess 21a, and the electrostatic chuck 100 is installed or positioned in the installation recess 21a. In addition, the fixed chuck 21 may be formed of a conductive material having excellent electrical conductivity, such as aluminum (Al), and may have a disk shape with a larger diameter than the electrostatic chuck 100.

A focus ring 24 surrounds or is positioned around the perimeter of the electrostatic chuck 100. As an example, the focus ring 24 may have a circular ring shape. The focus ring 24 may be formed of a conductive material, such as metal. The focus ring 24 may improve uniformity of a plasma sheath formed on the wafer by moving active ions or radicals of a source plasma to the periphery of the wafer. Accordingly, the source plasma formed in an internal space of the chamber 10 may be formed to be concentrated on an upper region of the wafer. The focus ring 24 may be formed of any one of silicon (Si), silicon carbide (SiC), silicon oxide (SiO₂), and aluminum oxide (Al₂O₃).

The upper electrode 30 is above the electrostatic chuck 100 and faces the susceptor 20. The upper electrode 30 may stabilize the atmosphere inside the chamber 10 during an etching process. The upper electrode 30 may be thick enough to allow high frequency power used for plasma etching to be transmitted therethrough sufficiently.

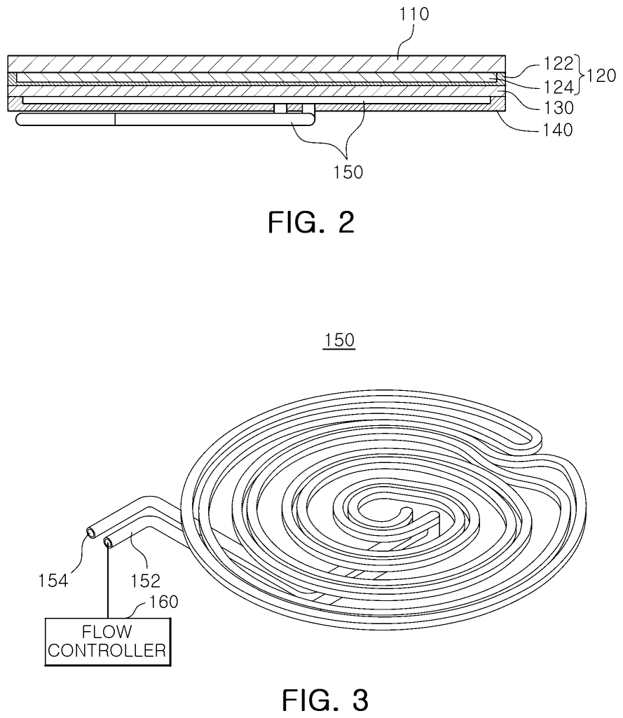

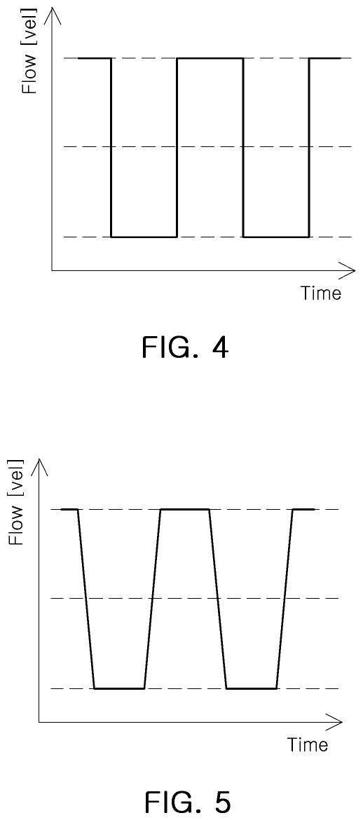

FIG. 2 is a cross-sectional view illustrating an electrostatic chuck according to an example embodiment, and FIG. 3 is a perspective view illustrating a coolant pipe provided in the electrostatic chuck according to an example embodiment.

Referring to FIGS. 2 and 3, the electrostatic chuck 100 according to an example embodiment includes a top plate 110, a heater portion 120, a buffer portion 130, a coolant pipe housing 140, and a coolant pipe 150.

In some embodiments, electrostatic chuck 100 may be used in semiconductor manufacturing equipment or semiconductor inspection equipment.

The top plate 110 may have a circular plate shape. As an example, a substrate, such as a wafer, may be seated on the top plate 110. The top plate 110 may be formed of ceramic material.

The heater portion 120 may be below the top plate 110. As an example, the heater portion 120 may include a heater housing 122 and a heater 124 inside the heater housing 122. The heater housing 122 has an internal space capable of accommodating the heater 124. As an example, the heater housing 122 may be formed of a material with high thermal conductivity so that heat generated from the heater 124 may be easily transferred to the top plate 110. The heater 124 may heat the top plate 110 to maintain the top plate 110 at a constant temperature.

The buffer portion 130 may be between the coolant pipe housing 140 and the heater portion 120. The buffer portion 130 may suppress heating of the coolant pipe housing 140 by the heater portion 120. As an example, the buffer portion 130 may reduce heat transfer from the heater 124 to the coolant pipe and/or prevent the coolant pipe 150 from being directly heated by the heater 124 of the heater portion 120.

The coolant pipe housing 140 may be in at least one of the chamber 10 or the electrostatic chuck 100. As an example, the coolant pipe housing 140 is below the buffer portion 130 of the electrostatic chuck 100 and has an internal space in which a portion of the coolant pipe 150 is positioned. As an example, the coolant pipe housing 140 may reduce or prevent damage to the coolant pipe 150.

The coolant pipe 150 is positioned such that a portion thereof is in the internal space of the coolant pipe housing 140 and a portion thereof is exposed from or outside of the coolant pipe housing 140. As an example, the portion of the coolant pipe 150 in the internal space of the coolant pipe housing 140 may have a curved shape, and the portion of the coolant pipe 150 outside of the coolant pipe housing 140 may have a straight shape. In addition, the coolant pipe 150 may have an inlet 152 through which the coolant flows in and an outlet 154 through which the coolant flows out. A pump (not shown) for circulation of the coolant may be connected to the coolant pipe 150.

Here, the coolant flowing along the coolant pipe 150 refers to a heat transfer medium. The coolant may be a heat transfer medium that heats the wafer or maintains the temperature of the wafer. In addition, the coolant may be liquid or gas.

The coolant may flow along the coolant pipe 150, while a flow velocity of the coolant changes. For example, the flow velocity of the coolant may be controlled by a flow controller 160 that is configured to control the flow velocity of the coolant as described in detail below.

In the present example embodiment, a case in which the coolant pipe housing 140 and the coolant pipe 150 are provided in the electrostatic chuck 100 is described as an example, but the present inventive concept is not limited thereto and the coolant pipe housing 140 and the coolant pipe 150 may be in the chamber 10.

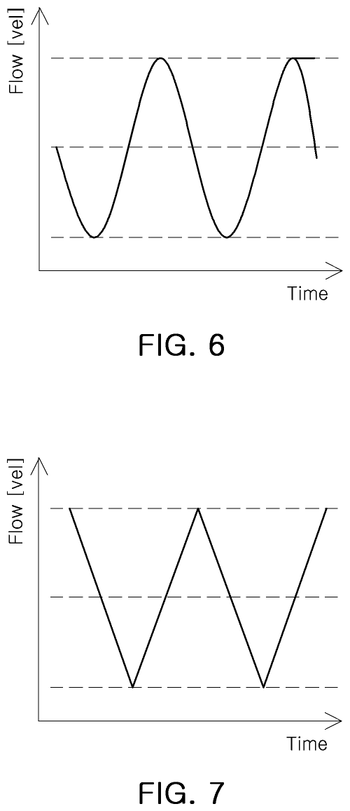

FIGS. 4 to 11 are graphs illustrating a flow velocity of a coolant flowing along a coolant pipe of an electrostatic chuck over time according to an example embodiment. In some embodiments, the flow velocity of the coolant as illustrated in FIGS. 4 to 11 may be controlled by the flow controller.

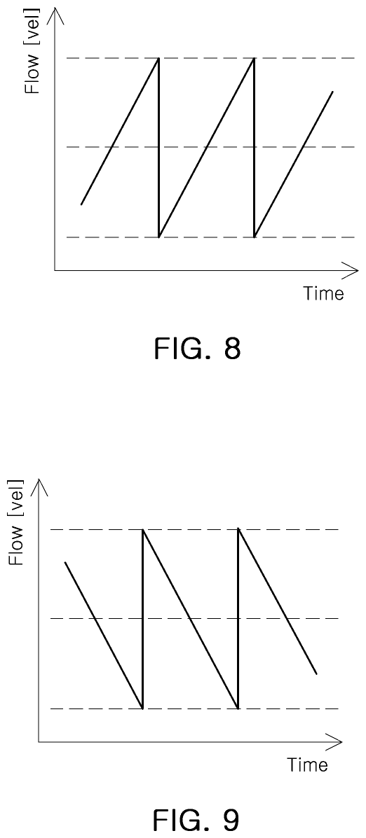

As an example, a flow velocity change waveform of the coolant may be any one of a square waveform as illustrated in FIG. 4, a ramp waveform as illustrated in FIG. 5, a sine waveform as illustrated in FIG. 6, a triangle waveform as illustrated in FIG. 7, or sawtooth waveforms as illustrated in FIGS. 8 and 9. In addition, the flow velocity change waveform of the coolant may be a combination of at least two of the square waveform, the ramp waveform, the sine waveform, the triangle waveform, and the sawtooth waveforms. As an example, the flow velocity change waveform of the coolant may be changed to a combination of a ramp waveform and a sine waveform as illustrated in FIG. 10 or a square waveform having different cycles as illustrated in FIG. 11.

Here, the flow velocity change waveforms of the coolant are defined as follows.

First, the square waveform refers to a shape in which a portion connecting the highest and lowest speeds is positioned to be vertical and the highest and lowest speeds are maintained for a certain period of time.

In addition, the ramp waveform refers to a shape in which a portion connecting the highest and lowest speeds is positioned to be inclined and the highest and lowest speeds are maintained for a certain period of time.

In addition, the sine waveform refers to a sine wave shape having inflection points at the highest and lowest speeds.

The triangle waveform repeatedly reaches the highest and lowest speeds and refers to a shape in which a portion connecting the highest and lowest speeds is positioned to be inclined.

In addition, the sawtooth waveform repeatedly reaches the highest and lowest speeds, in which a region in which the speed increases from the lowest speed to the highest speed is positioned to be inclined and a region in which the speed decreases from the highest speed to the lowest speed is positioned to be vertical. The sawtooth waveform repeatedly reaches the highest and lowest speeds, and a region in which the speed increases from the lowest speed to the highest speed is positioned to be vertical and a region in which the speed decreases from the highest speed to the lowest speed is positioned to be inclined.

In this manner, even if a constant flow velocity condition and an average flow velocity are maintained to be the same (i.e., a total flow rate is the same), the cooling ability (efficiency) may be increased by increasing the maximum speed through a combination of high and low flow velocities.

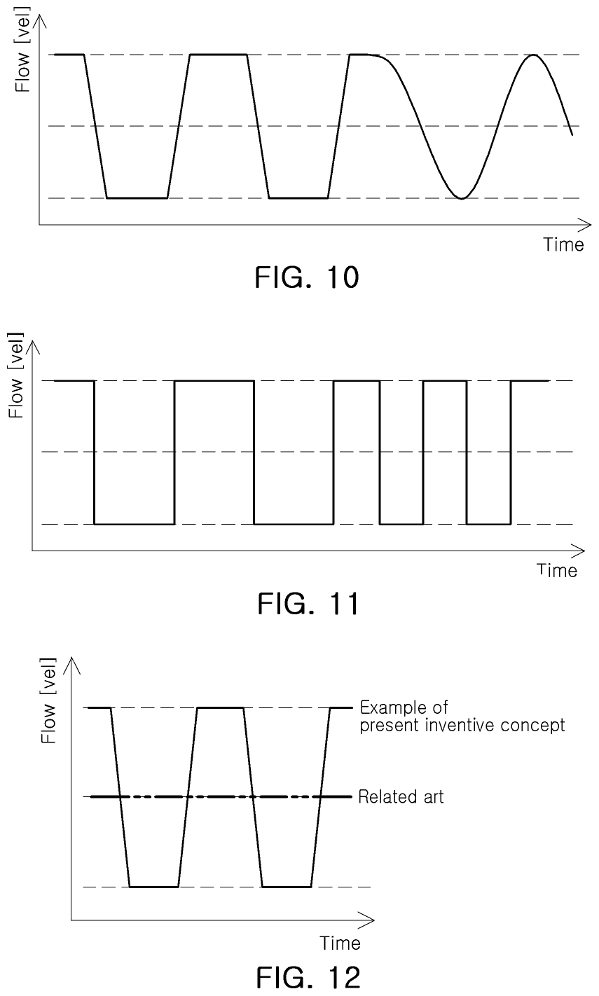

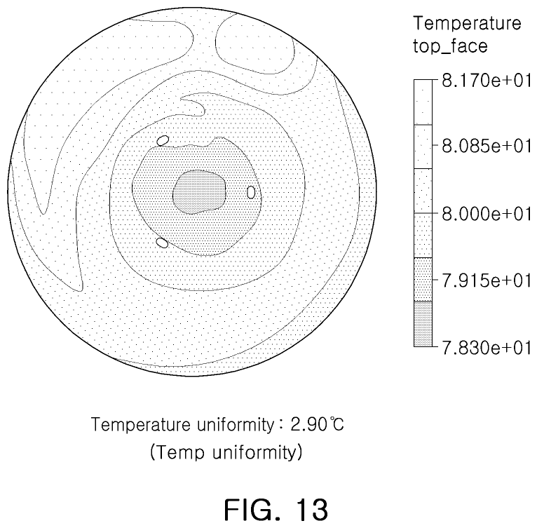

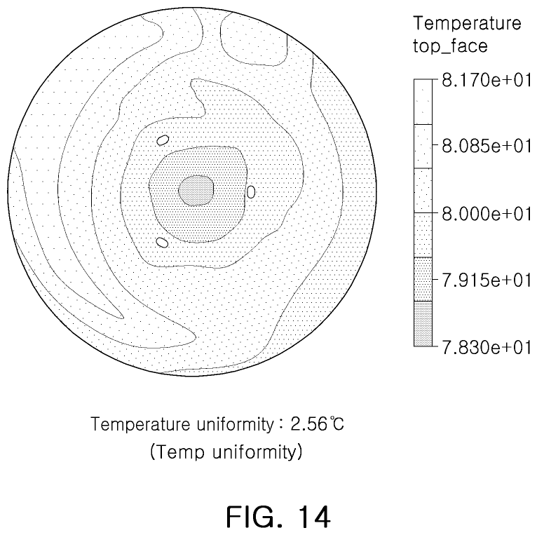

As an example, it can be seen that, when the wafer is cooled under constant flow velocity conditions as in the related art as illustrated in FIG. 12, temperature uniformity of the wafer is 2.90° C. in the temperature distribution as shown in FIG. 13, but when the wafer is cooled in the ramp waveform as a flow velocity of the coolant as shown in FIG. 12, the temperature uniformity of the wafer is 2.56° C. as shown in FIG. 14. In this manner, it can be seen that, when the flow velocity waveform of the coolant is changed to the ramp waveform, the temperature uniformity of the wafer is improved by 12%.

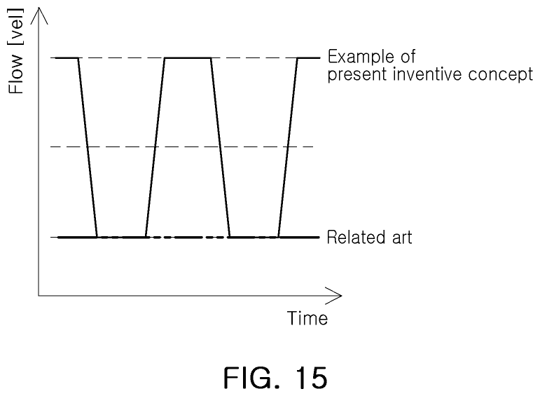

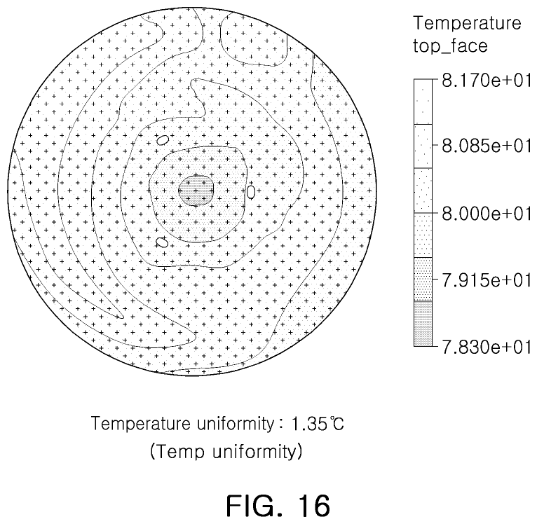

In addition, as an example, it can be seen that, when the flow velocity waveform of the coolant is the ramp waveform as illustrated in FIG. 15, the temperature uniformity of the wafer is 1.35° C. as illustrated in FIG. 16. In this manner, it can be seen that, when the flow velocity waveform of the coolant is changed to the ramp waveform, the temperature uniformity of the wafer is improved by 53%.

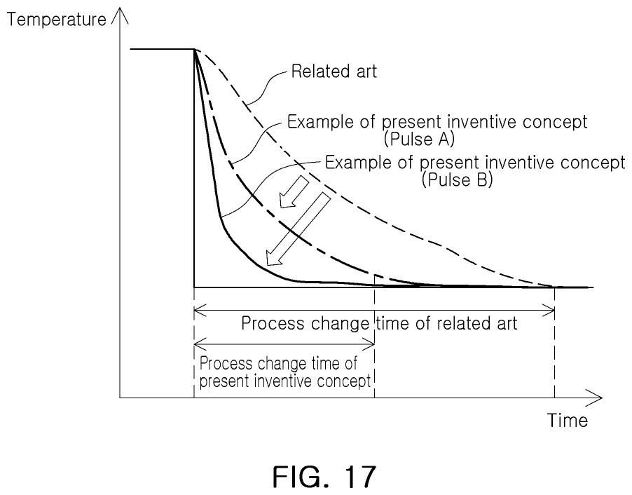

As illustrated in FIG. 17 together with FIGS. 12 and 15, it can be seen that, when the flow velocity waveform of the coolant is the ramp waveform, the process temperature stabilization time is shortened.

As described above, the temperature uniformity may be improved by changing the flow velocity waveform of the coolant flowing through the coolant pipe 150.

The effect of the etching device according to an example embodiment of the present inventive concept is described through experimental data.

TABLE 1

| | | | | Ratio of | Temper- | |
|---|---|---|---|---|---|---|
| Classi- | | Ratio of time | | flow | ature | Oscillating |
| fication | Cycle | occupancy | | velocity | uniformity | range |
| Related art | None | Constant flow | | 1.0 | 2.90° C. | — |
| Example 1 | 2 s | 50:50 | 1 s:1 s | 1.5:0.5 | 2.67° C. | 0.02° C. |
| Example 2 | 4 s | 50:50 | 2 s:2 s | 1.5:0.5 | 2.62° C. | 0.06° C. |
| Example 3 | 8 s | 50:50 | 4 s:4 s | 1.5:0.5 | 2.62° C. | 0.15° C. |

As illustrated in Table 1 above, it can be seen that, compared to the related art in which the coolant flows at a constant flow velocity as illustrated in FIG. 10, temperature uniformity is improved when the flow velocity has the square waveform as illustrated in FIG. 10. In other words, in the case of the related art, the temperature uniformity is 2.90° C., but when the flow velocity has the square waveform illustrated in FIG. 10 and the cycles are 2 s, 4 s, and 8 s, respectively, the temperature uniformity is improved to 2.67° C., 2.62° C., and 2.62° C., respectively. However, it can be seen that as the cycle increases, the temperature oscillation range increases.

TABLE 2

| | | | | Ratio of | Temper- | |
|---|---|---|---|---|---|---|
| Classi- | | Ratio of time | | flow | ature | Oscillating |
| fication | Cycle | occupancy | | velocity | uniformity | range |
| Related art | None | Constant flow | | 1.0 | 2.90° C. | — |
| Example 2 | 4 s | 50:50 | 2 s:2 s | 1.5:0.5 | 2.62° C. | 0.06° C. |
| Example 4 | 4 s | 25:75 | 1 s:3 s | 1.51:0.83 | 2.81° C. | 0.01° C. |

As illustrated in Table 2 above, in Example 4, when the ratio of flow velocity is 1.51, 25% of the total flow rate flows for 1 s, and when the ratio of flow velocity is 0.83, 75% of the total flow rate flows for 3 s. In this case, it can be seen that the temperature oscillation range is reduced, compared to Example 2. However, it can be seen that temperature uniformity deteriorates compared to Example 2 due to the decrease in flow rate in the high-speed flow region.

TABLE 3

| | | | | Ratio of | Temper- | |
|---|---|---|---|---|---|---|
| | | Ratio of time | | flow | ature | Oscillating |
| Classification | Cycle | occupancy | | velocity | uniformity | range |
| Related art | None | Constant flow | | 1.0 | 2.90° C. | — |
| Example 2 | 4 s | 50:50 | 2 s:2 s | 1.5:0.5 | 2.62° C. | 0.06° C. |
| Example 5 | 4 s | 25:75 | 1 s:3 s | 2.5:0.5 | 2.56° C. | 0.02° C. |

As illustrated in Table 3 above, it can be seen that, when the speed of the high-speed flow region is increased compared to Example 2, temperature uniformity is improved, and further, the temperature oscillation range is reduced compared to Example 2.

TABLE 4

| | | | | Ratio of | Temper- | |
|---|---|---|---|---|---|---|
| Classi- | | Ratio of time | | flow | ature | Oscillating |
| fication | Cycle | occupancy | | velocity | uniformity | range |
| Related art | None | Constant flow | | 1.0 | 2.90° C. | — |
| Example 3 | 8 s | 50:50 | 4 s:4 s | 1.5:0.5 | 2.62° C. | 0.15° C. |
| Example 6 | 8 s | 12.5:87.5 | 1 s:7 s | 1.49:0.93 | 2.84° C. | 0.01° C. |

As illustrated in Table 4 above, in Example 6, when the ratio of flow velocity is 1.49, 12.5% of the total flow rate flows for 1 s, and when the ratio of flow velocity is 0.93, 87.5% of the total flow rate flows for 7 s. In this case, it can be seen that the temperature oscillation range is reduced compared to Example 3. However, it can be seen that temperature uniformity deteriorates compared to Example 3 due to a decrease in flow rate in the high-speed flow region.

TABLE 5

| | | | | Ratio of | Temper- | |
|---|---|---|---|---|---|---|
| Classi- | | Ratio of time | | flow | ature | Oscillating |
| fication | Cycle | occupancy | | velocity | uniformity | range |
| Related art | None | Constant flow | | 1.0 | 2.90° C. | — |
| Example 3 | 8 s | 50:50 | 4 s:4 s | 1.5:0.5 | 2.62° C. | 0.15° C. |
| Example 7 | 8 s | 12.5:87.5 | 1 s:7 s | 2.47:0.79 | 2.68° C. | 0.05° C. |

As illustrated in Table 5 above, in the case of increasing the speed of the high-speed flow region and the speed of the low-speed flow region compared to Example 3, it can be seen that, the change in temperature uniformity is not significant, but temperature oscillation range is reduced compared to Example 3. The reason why the change in temperature uniformity is not significant is because the temperature uniformity is improved due to the increase in the speed of the high-speed flow region but the temperature uniformity deteriorates due to the decrease in a flow rate of the high-speed flow region.

Accordingly, a cooling system for semiconductor equipment capable of improving temperature uniformity of a wafer may be provided.

While example embodiments have been illustrated and described above, it will be apparent to those skilled in the art that modifications and variations could be made without departing from the scope of the present inventive concept as defined by the appended claims.

What is claimed is:

1. A cooling system for semiconductor equipment, the cooling system comprising:
a chamber;
an electrostatic chuck in the chamber;
a coolant pipe housing in at least one of the chamber and the electrostatic chuck, the coolant pipe housing having an internal space;
a coolant pipe at least partially in the internal space of the coolant pipe housing; and
a flow controller configured to control a flow velocity of a coolant flowing along the coolant pipe so that the flow velocity periodically reaches a highest speed and a lowest speed.

2. The cooling system of claim 1, wherein the flow controller is configured to control the flow velocity based on a flow velocity waveform of the coolant flowing along the coolant pipe comprising one of a square waveform, a ramp waveform, a sine waveform, a triangle waveform, and a sawtooth wave.

3. The cooling system of claim 1, wherein the flow controller is configured to control the flow velocity based on a flow velocity waveform of the coolant flowing along the coolant pipe comprising a combination of at least two of a square waveform, a ramp waveform, a sine waveform, a triangle waveform, and a sawtooth wave.

4. The cooling system of claim 1, wherein
the flow controller is configured to control the flow velocity based on a flow velocity waveform of the coolant flowing along the coolant pipe comprising one of a square waveform, a ramp waveform, a sine waveform, a triangle waveform, and a sawtooth waveform, and
the flow velocity waveform of the coolant flowing along the coolant pipe has a plurality of cycles.

5. The cooling system of claim 1, wherein
a time for which the highest speed is maintained and a time for which the lowest speed is maintained are the same.

6. The cooling system of claim 1, wherein
a time for which the highest speed is maintained and a time for which the lowest speed is maintained are different.

7. The cooling system of claim 5, wherein a total flow rate during the time for which the highest speed is maintained and a total flow rate during the time for which the lowest speed is maintained are the same.

8. The cooling system of claim 6, wherein a total flow rate during the time for which the highest speed is maintained and a total flow rate during the time for which the lowest speed is maintained are different.

9. The cooling system of claim 1, wherein the coolant flowing along the coolant pipe is liquid or gas.

10. The cooling system of claim 1, wherein the coolant flowing along the coolant pipe is configured to heat a wafer or to maintain a temperature of the wafer.

11. A cooling system for semiconductor equipment, the cooling system comprising:
a chamber; and
an electrostatic chuck in the chamber,
wherein the electrostatic chuck includes:
a top plate on which a wafer is seated;
a coolant pipe housing below the top plate and having an internal space; and
a coolant pipe at least partially in the internal space of the coolant pipe housing;
wherein the cooling system further comprises a flow controller configured to control a flow velocity of a coolant flowing through the coolant pipe so that the flow velocity changes periodically over time.

12. The cooling system of claim 11, wherein the flow controller is configured to control the flow velocity based on a flow velocity waveform of the coolant flowing along the coolant pipe comprising one of a square waveform, a ramp waveform, a sine waveform, a triangle waveform, and a sawtooth wave.

13. The cooling system of claim 11, wherein the flow controller is configured to control the flow velocity based on a flow velocity waveform of the coolant flowing along the coolant pipe comprising a combination of at least two of a square waveform, a ramp waveform, a sine waveform, a triangle waveform, and a sawtooth wave.

14. The cooling system of claim 11, wherein
the flow controller is configured to control the flow velocity based on a flow velocity waveform of the coolant flowing along the coolant pipe comprising one of a square waveform, a ramp waveform, a sine waveform, a triangle waveform, and a sawtooth waveform, and
the flow velocity waveform of the coolant flowing along the coolant pipe has a plurality of cycles.

15. The cooling system of claim 11, wherein
the flow controller is configured to control the flow velocity so that the flow velocity of the coolant flowing along the coolant pipe periodically reaches a highest speed and a lowest speed, and
a time for which the highest speed is maintained and a time for which the lowest speed is maintained are the same.

16. The cooling system of claim 15, wherein a total flow rate during the time for which the highest speed is maintained and a total flow rate during the time for which the lowest speed is maintained are the same.

17. The cooling system of claim 11, wherein
the flow controller is configured to control the flow velocity so that the flow velocity of the coolant flowing along the coolant pipe periodically reaches a highest speed and a lowest speed, and
a time for which the highest speed is maintained and a time for which the lowest speed is maintained are different.

18. The cooling system of claim 17, wherein the time for which the highest speed is maintained is shorter than the time for which the lowest speed is maintained.

19. The cooling system of claim 18, wherein a total flow rate during the time for which the highest speed is maintained and a total flow rate during the time for which the lowest speed is maintained are different.

20. The cooling system of claim 19, wherein the total flow rate during the time for which the highest speed is maintained is less than the total flow rate during the time for which the lowest speed is maintained.
